(19) United States
(12) Patent Application Publication
(10) Pub. No.: US 2016/0109530 A1
(43) Pub. Date: Apr. 21, 2016

(54) COMBINATION OF A BATTERY STACK AND A BATTERY MONITOR, AND A METHOD OF CONNECTING A BATTERY MONITOR TO A STACK OF BATTERIES

(71) Applicants: Jeremy R. GORBOLD, Newbury (GB); Colin Charles PRICE, Newbury (GB)

(72) Inventors: Jeremy R. GORBOLD, Newbury (GB); Colin Charles PRICE, Newbury (GB)

(73) Assignee: ANALOG DEVICES TECHNOLOGY, Hamilton (BM)

(21) Appl. No.: 14/520,013

(22) Filed: Oct. 21, 2014

(51) Int. Cl. G01R 31/36; H02J 7/00; H01R 43/26

(52) U.S. Cl. CPC G01R 31/3696; G01R 31/3658; H01R 43/26; H02J 7/0029

(57) ABSTRACT

Battery monitors are provided in association with battery stacks to monitor the health of individual batteries. This is important as damaged batteries present a fire risk. Usually the battery stack is assembled and connected to a multipin connector assembled and connected to a multipin connector which engages with a cooperating connector of a battery monitor. The connections have a tolerance so the connections make in a random and uncontrolled order. This disclosure provides ways of ensuring that the power supply connector connects first. This reduces voltage stress in the monitoring circuit and also allows steps to be taken to control inrush currents.

### FIELD

This disclosure relates to a way of connecting a battery monitoring system to a group of batteries, for example as might be found in a hybrid or battery powered automobile. It is desirable to avoid the battery monitoring system being electrically stressed during the process of connecting it to a battery stack. This disclosure addresses this problem.

### BACKGROUND

High voltage batteries are becoming increasingly common. An example of such a use is hybrid and electric vehicles where a plurality of lithium ion batteries are connected together to form a battery stack which looks like a high voltage battery. It is known that the charge and condition of each individual lithium ion battery within the battery stack should be monitored in order to ensure longevity of the battery system, and to take appropriate action if one of the cells get excessively hot. It is particularly important to avoid lithium ion batteries from becoming too hot because if they catch fire then they cannot be put out because combustion of the battery generates sufficient oxygen in order to continue combustion.

Typically the battery stack may contain a large number of individual cells. For example, the battery pack for a Chevrolet Volt contains 288 cells. Individual cells may be monitored, or small groups of cells may be monitored in order to determine battery performance.

Typically the battery pack or battery stack is at least 30% charged at the time that the stack is manufactured. Whilst this leads to a lower cell voltage, the cells cannot be further discharged without adversely affecting the lifetime of the battery. A wiring harness makes a plurality of contact points within the battery stack and is generally terminated by a suitable connector, such as a multipin socket. The battery is monitored by a monitoring system which is connected to the multipin socket by way of a multipin plug. When the plug and socket are introduced together for the first time there is no control over which one or ones of the contacts make electrical connection first. Furthermore, the operative connecting the plug and socket may introduce them at an angle, may press one end before the other and so on. Thus the components of the battery monitoring system may be exposed to the plurality of battery voltages within the battery stack in an uncontrolled and random order. This can adversely affect the durability of components in such a monitoring system, or lead to increased cost of such a monitoring system in order to provide additional protection to it to ensure that it can survive any sequence of connections being made to the battery.

### SUMMARY

According to a first aspect of this disclosure there is provided a plug and a socket for use with a battery stack and a battery monitor for monitoring batteries within the battery stack. Dimensions, positions or shapes of first and second connection elements within the plug and/or within the socket are adapted to cause the first and second connection elements to make contact with cooperating connection elements prior to the remainder of the connection elements making contact.

It is thus possible to arrange for the supply rails of a battery monitoring circuit which receives its power from the battery to become energized before any other connections are made. This enables voltages within the battery monitoring circuit to become adequately established in order to prevent voltage stresses developing.

In accordance with a further aspect of this disclosure there is provided a combination of a battery stack and battery monitor having a plug and socket combination arranged to cause two connections to be placed in current flow and communication before the remainder of the connections of the plug and socket combination.

Advantageously the two connections are first and second connections which are made to opposing ends, or substantially opposing ends, of the battery stack such that the full stack voltage or substantially the full stack voltage or other voltage is appropriate for the design of the monitoring circuit is delivered as a power supply for the battery monitoring circuit.

Even when the plug and socket combination are organized such that the power supply connections are made first when the plug and socket are connected, the high voltage across the battery stack may still lead to large initial current flows, known as inrush currents, which may adversely affect components within the battery stack, or could create sparking or arcing that may damage the contacts of the plug and socket. Advantageously inrush current limiting components may be included in the wiring or conduction paths to the first and second connection elements, or at least to one of them.

Additional current flow paths may be formed once the inrush current has subsided. This can be achieved by providing additional connectors on the plug which make further paths to the opposing terminals of the battery stack. Additionally or alternatively components may be provided for by bypassing the inrush current limiting components, for example by using transistor or mechanical switches to open a shunt path around the inrush current limiting component.

According to a further aspect of this disclosure there is provided a method of forming a combination of a battery stack and the battery monitor for the battery stack, the method comprising forming a battery stack with a plurality of battery nodes connected to respective contacts of a first connector, and where first and second ones of the contacts are connected to battery nodes substantially at or at opposing ends of the battery stack; forming a battery monitoring circuit connected to a second connector arranged to be connectable with the first connector; and adapting conductor sizes or positions within at least one of the first and second connectors such that the first and second contacts are the first connections to be made when the first and second connectors are brought into connection with each other.

Adapting the sizes or positions of the connectors may, for example, involve lengthening pins associated with the first and second contacts of a plug, lengthening a conducting sheath or cylinder or repositioning contacts associated with the first and second contacts within a socket or modifying the plug and socket that the action of coupling them together requires the contacts to be introduced in such a way that an order of connection can be guaranteed. As a further alternative, a connection inhibiting component or material may be placed adjacent or over selected conductors within, for example, a plug and socket combination. Thus, for a socket, a thin insulating film may be placed over the majority of the connectors of the socket, with apertures in the film left open for the first and second contacts. The film may be a thin insulating plastic film which is arranged to stretch during an initial phase of insertion of the plug into the socket, but to mechanically fail during the insertion process so as to allow electrical contact to be made. Thus an order of connection can be made by use of an intermediate component, such as a film, rather than modifying the plug and socket as such.

As a further option a suitably shaped adapter may be used to introduce thin conducting filaments into the sockets corresponding to the first and second connectors such that these filaments reduce the gap within the plug and socket combination between cooperating connectors such that the first and second connectors naturally form the first current flow path. Furthermore, the resistance of the thin filaments can be used to limit inrush currents.

### BRIEF DESCRIPTION OF THE FIGURES

Embodiments in accordance with this disclosure will now be described, by way of non-limiting example only, with reference to the accompanying figures, in which:

FIG. 1 is a circuit diagram of a battery stack in combination with a battery monitor;

FIG. 2 is a cross-section through a connector suitable for connecting the battery stack to the battery monitor;

FIG. 3 is a circuit diagram showing embodiment of a battery stack and monitoring circuit in accordance with this disclosure; and

FIG. 4 shows a further embodiment of a battery stack and battery monitor.

### DESCRIPTION

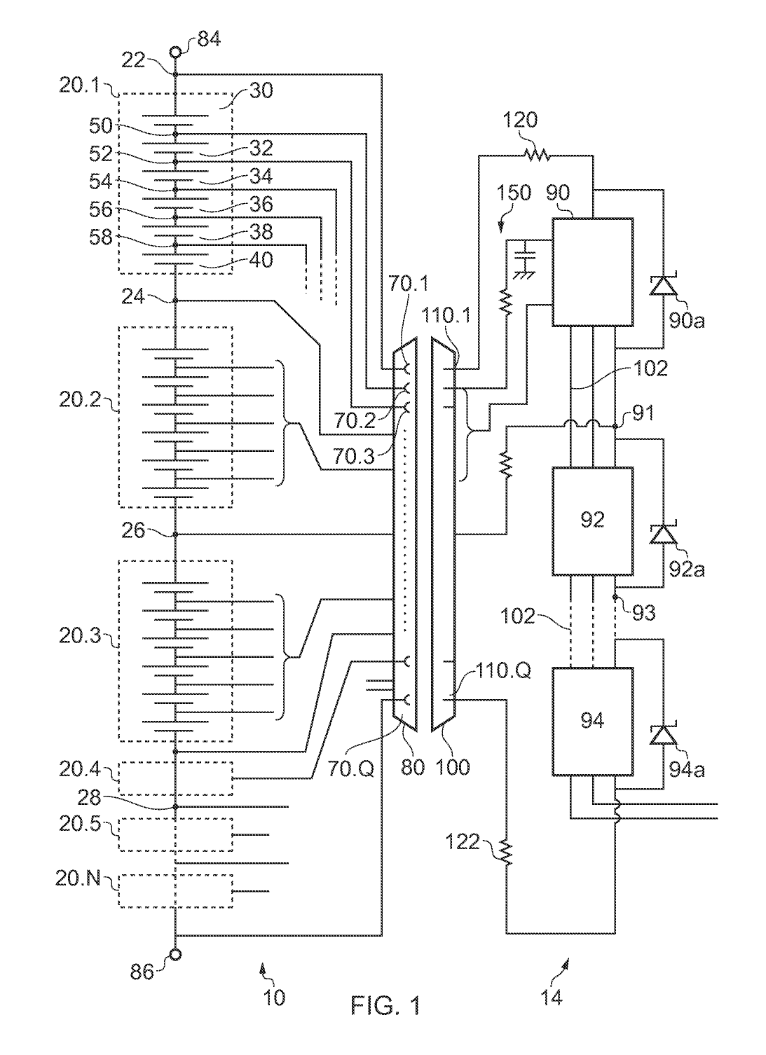

FIG. 1 schematically illustrates a battery stack, generally designated 10, in combination with a battery monitor, generally designated 14. In order to aid manufacture, the individual cells of the battery stack may be subdivided into a plurality of battery packs designated 20.1, 20.2, 20.3 and so on to 20.N, where N represents the number of individual packs within the battery stack. Each battery pack may itself contain a plurality of cells. In the example shown in FIG. 1, each battery pack contains six cells, the battery packs can be assumed to be the same, and therefore for brevity only the first battery pack 20.1 will be described in detail.

The first battery pack 20.1 has an anode 22 and a cathode 24. Six cells 30, 32, 34, 36, 38 and 40 are arranged in series within the battery pack 20.1 with the cathode of one cell connected to the anode of its neighbor. A plurality of intermediate nodes are formed. Thus an intermediate node 50 is formed between the cathode of the first cell 30 and anode of the second cell 32. Similarly a second node 52 is formed between the cathode of the second cell 32, and the anode of the third cell 34. Intermediate nodes 54, 56 and 58 are also formed. Connections may be made to the anode and cathode of the first battery pack 20.1 and to each of the intermediate nodes 50, 52, 54, 56 and 58 between its cells 30, 32, 34, 36, 38 and 40. Each of these connections may be taken to a respective contact or socket, 70.1, 70.2, 70.3 and so on within a first connector 80. Similar connections are made for the other battery packs 20.2 to 20.N.

Some reduction in the number of connectors can be achieved because the anode of one battery pack is often the cathode of its neighboring battery pack and hence only one rather than two connections are required at these nodes. Similarly, it is also possible if necessary to reduce the number of connections to the intermediate nodes such that rather than each individual cell 30, 32, 34, and so on being monitored, pairs of cells or indeed small groups of cells may be monitored rather than individual cells. High current and high voltage connections are made to the battery pack by way of terminals 84 and 86.

The battery monitor 14 may comprise a plurality of monitoring integrated circuits, such as the AD7283 by Analog Devices which are able to monitor the battery voltages across a plurality of cells, and to pass this information via a daisy chained serial data bus such that cell voltages for the entire battery stack can be monitored. In the arrangement shown here, each one of the monitoring circuits 90, 92 and 94 can monitor the cells of two of the battery packs. Although only three monitoring circuits have been shown for simplicity more or fewer may be provided. Thus the first monitoring circuit 90 monitors the first and second battery packs 20.1 and 20.2. The second monitoring circuit 92 can monitor the third and fourth battery packs 20.3 and 20.4 respectively, and so on. The monitoring circuits 90, 92 and 94 are connected to the anode and cathode of the battery pack 10 by way of connectors 70.1 and 70.Q. The battery monitoring circuits 90, 92 and 94 are arranged in series such that when a plug 100 of the battery monitoring circuit 14 is connected to the socket 80 of the battery stack 10 the battery stack voltage is applied across the series connected monitoring circuits 90, 92 and 94. The voltage across each of the circuits 90, 92, 94 is limited by a respective parallel connected Zener diode, 90a, 92a, 94a, which is selected such that, in this example, roughly one third of the battery voltage is dropped across each one of the battery monitoring circuits 90, 92 and 94. If four circuits were provided then one quarter of the battery circuit would be dropped across each circuit, if five provided then one fifth across each circuit, and so on.

This voltage sharing arrangement means that the integrated circuits 90, 92, 94 are not required to be able to withstand the entirety of the battery pack voltage. This allows them to be made using less expensive semiconductor fabrication processes which are more amenable to the formation of digital logic components, such as analog to digital converters, state machines and so on provided within each one of the circuits 90, 92 and 94 in order to enable them to perform their measuring function, to encode the measurements in a suitable form, and then to pass those measurements along a daisy chained data bus indicated 102. The nodes between individual ones of the battery packs can, if they are at a suitable voltage, be connected to the voltage supply node intermediate adjacent ones of the series connected measuring circuits. This enables the voltage drop across each one of the measuring circuits to be relatively well defined.

In the example shown in FIG. 1 the node 26 between the second battery pack 20.2 and the third battery pack 20.3 is connected by way of the plug and socket combination to a node 91 in the power supply chain between measuring circuits 90 and 92. Similarly a node 28 between the fourth and fifth battery packs 20.4 and 20.5 is connected by way of the plug and socket combination to a node 93 between the second and third measuring circuits 92 and 94. This can be continued as necessary. This ensures that once the plug and socket 100 and 80 are connected, the voltage across each one of the measuring circuits is referenced to specific nodes within the battery stack and the Zener diodes 90a, 92a and 94a need no longer be conducting.

The plug 100 has pins 110.1 to 110.Q for making connection with the sockets 70.1 to 70.Q within the corresponding socket connector 80.

A problem with this multipin plug and socket configuration is that necessarily some tolerance on pin and socket position must be provided in order to ensure that all of the connections can make contact when the plug and socket are fully engaged. This positional tolerance, coupled with limited flexibility of the material making the plug and socket, means that the order in which the connections are made when the plug and socket are connected together is ill defined, and any one of the voltages at any one of the nodes in the battery pack may be the first voltage applied to the monitoring circuit. A close to worst case scenario would be if the first connection to be made is that of connection 70.2 corresponding to just one cell short of the high voltage terminal of the battery stack and the next connection is an input pin close the bottom of the battery stack. If, as might be reasonable, all of the measuring circuits 90, 92 and 94 are at a ground voltage, then the potential difference at one of the input pins of the measuring circuit 90 could be substantially the entire voltage of the battery stack. This may cause damage to the signal handling components within the circuit 90. Such a voltage might, for example, punch through the insulation of a field effect transistor used as a sampling switch as part of an analog to digital converter or as a switch within a multiplexor. The circuit can partially be protected by including a low pass filter 150 formed of a resistor and capacitor combination at the input to the circuit 90, in the hope that this delays the voltage rise at the input whilst other ones of the connections become connected and the power supply connections 70.1 and 70.Q become connected. Whilst provision of such a low pass filter arrangement 150 can protect the integrated circuits, it can bring its own problems because all this extra capacitance takes space, and also needs to be charged when connections are made. The filter 150 in FIG. 1 is associated with node 50 of the battery stack. Further filters (not shown) are provided in association with nodes 52, 54, 56 and so on.

Investigations show that elapsed time from the first contact being made to the last contact being made is normally in the range of 10-20 milliseconds. Whilst this is not long, this should be compared with the Latchup testing performed on automotive parts which generally requires them to survive a current of 100 milliamps for around 5 milliseconds. Thus the connection stress may be in excess of the rated Latchup tolerance of the components.

The inventor noted that it would be desirable to be able to ensure that the power rail for the monitoring circuits 90, 92 and 94 became established before connections were made to the various intermediate nodes 24, 26, 28, 50, 52, 54, 56 and so on. This is because each one of the monitoring circuits 90, 92 and 94 can rapidly move to a respective voltage domain where the voltage at its input pins is much closer to voltage at the intermediate nodes, such that surge currents are reduced as these monitoring connections are made.

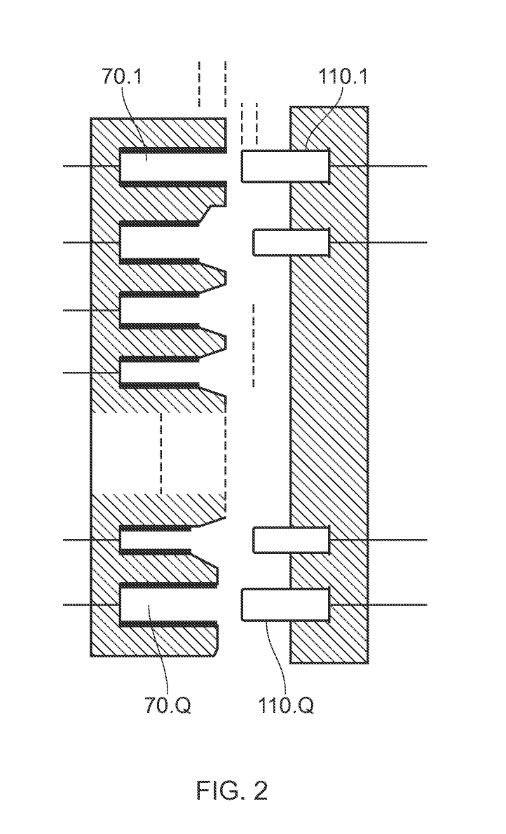

This feature, namely establishing the power supply for the monitoring apparatus 14 can be achieved by modifying either one or both of the plug 100 and socket 80 such that the pin and corresponding connector 100.1 and 70.1 and pin and corresponding connector 110.Q and 70.Q interengage with each other before any other of the pin and connector combinations 70.2, 100.2, to 70.Q−1, 100.Q−1. This can be achieved, as shown in FIG. 2, by lengthening pins 100.1 and 100.Q compared to any of the other pins, and/or extending the length of the conductive piece of the socket 70.1 and 70.Q compared to any other ones of the sockets. In an alternative approach, the pin and socket lengths may be kept roughly the same, but small additional contact elements could be inserted into socket 70.1 and 70.Q, for example by way of a jig allowing small spring like or filamentous conductors to be inserted into the appropriate sockets.

Whilst ensuring that the supply rails for the measuring circuit become established first is advantageous in many aspects, it does mean that a large inrush current can flow into the integrated circuits, and to any capacitors associated with them for power supply smoothing. Thus, if the series resistor 120 connecting pin 110.1 to the positive supply terminal of the monitoring circuit 90 has a value of, say, 20 ohms and the battery stack comprises 96 cells with a nominal voltage of 3 volts each, then the initial surge current through the 20 ohm resistor 120 could be in the order of 14.4 amps. Thus this requires the use of a surge rated resistor in order to avoid damage, thereby incurring additional cost. It is therefore beneficial to increase the value of the resistor 120 in order to limit the inrush current. Thus if the resistors 120 had a value of 10 kilo-ohm each then the inrush current would be limited to 14.4 milliamps. If the resistors were 1 kilo-ohm then the inrush current would be limited to 144 milliamps. While these larger values of resistances limit the inrush current, they may fail to provide the current flow acquired to power the monitoring circuit correctly.

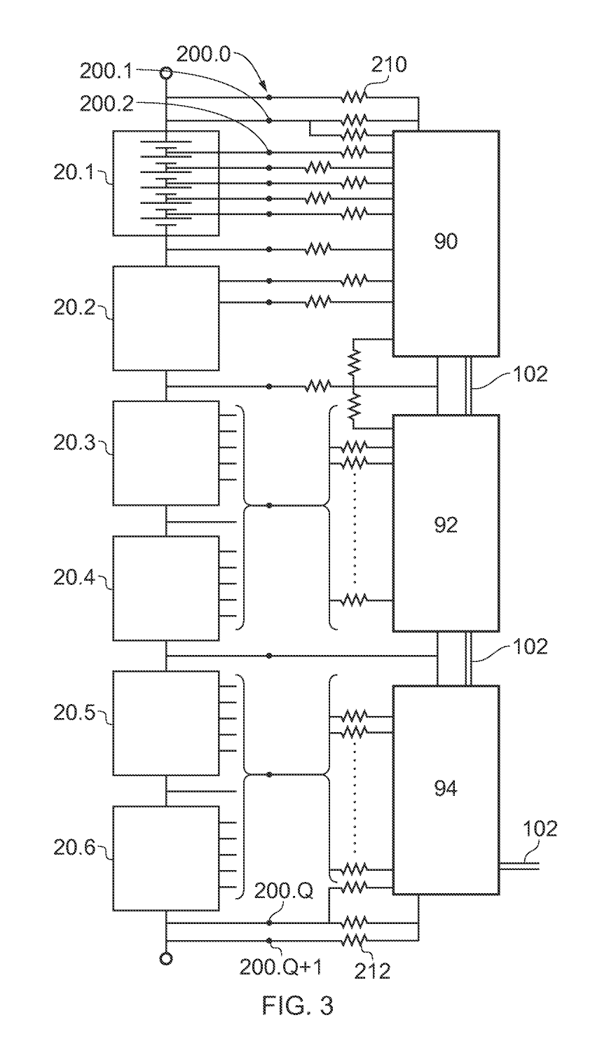

The inventor realized that this problem could be solved, as shown in FIG. 3, by the inclusion of additional pins within the connector and socket combination such that the initial connection could be made via a relatively high resistance path in order to limit the inrush current, but as the plug and socket were brought fully into engagement, a second power supply path having a lower resistance is opened thereby ensuring that the monitoring circuit is properly powered.

The arrangement shown in FIG. 3 is similar to that of FIG. 1. Thus six battery packs 20.1 to 20.6 are connected in series. Only the batteries within the first battery pack have been illustrated, but the other battery packs are to be understood to be like the first battery pack 20.1. The monitoring circuits 90, 92 and 94 are provided in series connection as described herein before with respect to FIG. 1.

For diagrammatic simplicity the connections made by the plug 80 and socket 100 combination of FIG. 1 are designated by nodes 200.1 to 200.Q.

However now at least one, and preferably two extra connections are provided. These are designated 200.0 and 200.Q+1.

These extra connections may be provided on the multipin connectors 80 and 100, and if so these connections are provided with the elongated pins/sockets or other adaptations to ensure that these two connections are the ones that make first. Thus these would be allocated to the endmost connections of the plug and socket shown in FIG. 2.

As an alternative, they could be allocated to an additional two pin connector that is to be connected prior to the multipin connector that carries to connections 200.1 to 200.Q.

The additional current flow paths via the connections/nodes 200.0 and 200.Q+1 are associated with resistors 210 and 212 which connect to the positive supply of the first measurement circuit 90 and to the negative supply of the last measurement circuit 94. The resistors are selected to limit the inrush current. Thus rather than being, say around 20 ohm as described with respect to FIG. 1, the resistors 210 and 212 may be larger, say 1K, 2K, 5K 10K and so on.

Using 10K resistors would provide a series resistance of 20K and limit the inrush current to 288/20000=14.4 mA.

The inrush current limiting resistors 210 and 212 still allow the internal voltages to become established before the measurement connections 200.1 to 200.Q are made. It can also be seen that the current limiting resistors get bypassed when the connections 200.1 and 200.Q are made.

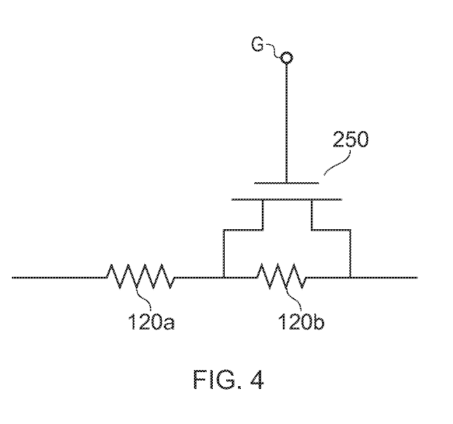

As a further alternative, and returning to the circuit configuration of FIG. 1, the resistors 120 and 122 in series with the supply terminals of the series connected measurement circuits may be placed in series with a further component such as an additional resistor and transistor or switch that can short the additional resistor out; or with a series connected FET that can act as a controllable resistance. Thus the effective resistance could start high, and then be controlled to reduce. This may be used to avoid forming extra connections at the connectors (i.e. the plug and socket). Such an arrangement is shown in FIG. 4.

Here resistor 120 is replaced by resistors 120a and 120b. Resistor 120a has a low value, say in the order of 10 to 50 ohms whereas resistor 120b is significantly larger, possibly several kilo-ohms.

A transistor 250 is provided in parallel with resistor 120b, and may initially be in a high impedance state and become switched to a low impedance state in response to a control signal applied to its gate G. The control signal may be generated by a RC timer. The transistor may be P-type or N-type depending on the circuit designer's preference.

Additionally or alternatively inductors may be included in the power supply path to limit inrush currents.

An alternative approach to extending the metal connective part of the contacts within, for example, the socket is to have all the contacts substantially the same length, but introduce an insulator which prevents contact being made during an initial stage of insertion of the plug into the socket for selected ones of the contacts. This may be achieved by placing a thin non-conducting film over the majority of the surface of the socket, leaving only selected apertures of the socket uncovered, such as those corresponding to connectors 70.1 and 70.Q. Thus the film inhibits connection for most of the connectors during the insertion process, until such time as the pins of the plug overstretch the film and rupture it, thereby allowing the pins to make contact with the metallic portions of the socket.

It is thus possible to protect the monitoring circuit from damage due to the possibility of any make order connection by the plug and socket combination used to connect the monitoring circuit to the battery stack.

Several embodiments of the invention are specifically illustrated and/or described herein. However, it will be appreciated that modifications and variations of the invention are covered by the above teachings and within the purview of the appended claims without departing from the spirit and intended scope of the invention.

1. A plug and socket for use with a battery stack and a battery monitor for monitoring batteries within the battery stack, wherein the dimensions of first and second connection elements within the plug and/or within the socket are adapted to cause the first and second connection elements to make contact with cooperating connections elements prior to the remainder of the connection elements making contact.

2. A battery stack and battery monitor having a plug and socket as claimed in claim 1 for connecting the battery stack with the battery monitor.

3. A combination of a battery stack and battery monitor as claimed in claim 2, in which the first and second connections are made to substantially opposing ends of the battery stack.

4. A combination of a battery stack and battery monitor as claimed in claim 1, in which the first and second connection elements are in a path with at least one inrush current limiting component.

5. A combination of a battery stack and battery monitor as claimed in claim 4, in which the at least one inrush limiting component is a resistance and/or an inductance.

6. A combination of a battery stack and battery monitor as claimed in claim 5, in which the inrush current limiting components are resistors having a value in excess of 1 kilo ohm, and said inrush current limiting components are bypassed after an initial connection has been made.

7. A combination of a battery stack and battery monitor as claimed in claim 1, where the battery monitor comprises a plurality of monitoring devices, each operating in a respective voltage domain in use.

8. A battery monitor comprising a plurality of monitoring circuits connected in series such that each has positive and negative power supplies defining a respective voltage domain, and a connector adapted to cause two supply contacts to make connection before any other of the contacts in the connector make connection.

9. A battery monitor as claimed in claim 8 in which, in use, the two supply contacts are connected to the anode and cathode terminals of the battery stack, respectively.

10. A battery monitor as claimed in claim 9 in which the two supply contacts provide power to the battery monitor via current limiting components.

11. A battery monitor as claimed in claim 8 in which a plurality of monitoring circuits are arranged in a chain, and data and/or commands are passed along the chain and voltage domain translated at each device.

12. A method of connecting a plug and socket comprising a first step of applying an intermediate element to delay connection of a majority of the cooperating connectors of the plug and socket compared to first and second pairs of cooperating connectors, and subsequently connecting the plug and socket together such that the connection process enables selected current flow paths to open before other ones of the current flow paths.

13. A method as claimed in claim 12, in which the intermediate element is an elongated connector.

14. A method as claimed in claim 12 in which the selected current flow paths further include inrush current limiting elements.

15. A method as claimed in claim 14 in which the inrush current limiting elements are bypassed or shunted when the majority of the cooperating connectors become connected.
